(19) United States
(12) Patent Application Publication
(10) Pub. No.: US 2023/0274917 A1
(43) Pub. Date: Aug. 31, 2023

(54) CARRIER DEVICE AND SEMICONDUCTOR REACTION CHAMBER

(71) Applicant: BEIJING NAURA MICROELECTRONICS EQUIPMENT CO., LTD., Beijing (CN)

(72) Inventors: Jinji XU, Beijing (CN); Xingfei MAO, Beijing (CN)

(21) Appl. No.: 18/313,027

(22) Filed: May 5, 2023

Related U.S. Application Data
(63) Continuation of application No. PCT/CN2021/127291, filed on Oct. 29, 2021.

(30) Foreign Application Priority Data
Nov. 5, 2020 (CN) 202011224676.0

(51) Int. Cl. H01J 37/32; H01L 21/683; H01L 21/67

(52) U.S. Cl. CPC H01J 37/32642; H01L 21/6831; H01L 21/67069

(57) ABSTRACT

A carrier device is configured to carry a wafer in a semiconductor reaction chamber. The carrier device includes a chuck, a focus ring assembly, and a plurality of focus ring thimbles. The chuck is arranged in the semiconductor reaction chamber to support the wafer. The focus ring assembly includes a lower focus ring and an upper focus ring. The lower focus ring is arranged around the chuck. The lower focus ring includes a groove on an upper surface of the lower focus ring. A part of an upper surface of the lower focus ring located on an inner side of the groove is a support area. A first position-limiting member is arranged on a lower surface of the upper focus ring and corresponds to the groove. The plurality of focus ring thimbles are distributed along a circumference of the upper focus ring at intervals.

### CROSS-REFERENCES TO RELATED APPLICATIONS

This application is a continuation of International Application No. PCT/CN2021/127291, filed on Oct. 29, 2021, which claims priority to Chinese Application No. 202011224676.0 filed on Nov. 5, 2020, the entire content of all of which are incorporated herein by reference.

### TECHNICAL FIELD

The present disclosure generally relates to the semiconductor manufacturing technology field and, more particularly, to a carrier device and a semiconductor reaction chamber.

### BACKGROUND

As technology continues to develop, electronic products such as smartphones and tablet computers are widely used. Electronic products include many semiconductor chips. A major material for manufacturing a semiconductor chip is a wafer. A circuit pattern needs to be etched on the wafer. Generally, the wafer is etched by a semiconductor process apparatus.

Taking an etching machine as an example, an electrostatic chuck and a focus ring are arranged in the semiconductor reaction chamber of the etching machine. The electrostatic chuck is configured to support the wafer. The focus ring is arranged around the electrostatic chuck. The focus ring can focus the plasma in the semiconductor reaction chamber to improve etching uniformity.

However, in an etching process of the wafer in the semiconductor reaction chamber, since the top surface of the focus ring and an upper surface of a groove are also etched, the thickness of the focus ring is reduced. Thus, an etching rate of an edge of the wafer is increased. Therefore, the difference between an etching rate at an edge area of the wafer and an etching rate at a center area of the wafer can be large, which causes poor etching uniformity. To increase the etching uniformity, after the top surface of the focus ring and the upper surface of the groove are etched, the focus ring can be lifted by a thimble driven by a driving mechanism. Thus, the part of the focus ring that is etched can be compensated by increasing the height of the focus ring to ensure the etching uniformity.

However, since the focus ring is only arranged on the thimble, on one hand, when the driving mechanism drives the thimble to lift the focus ring, the position of the focus ring on the thimble can be displaced. Thus, when the displaced focus ring lifts the wafer, the height of the wafer can be changed, which affects absorption and position precision of the wafer to impact the etching process. On another hand, when the focus ring is subjected to a push force of the thimble when the thimble lifts the focus ring up, the focus ring may easily fall off from the thimble. Thus, the safety of the semiconductor reaction chamber is poor.

### SUMMARY

Embodiments of the present disclosure provide a carrier device configured to carry a wafer in a semiconductor reaction chamber. The carrier device includes a chuck, a focus ring, and a plurality of focus ring thimbles. The chuck is arranged in the semiconductor reaction chamber to support the wafer. The focus ring assembly includes a lower focus ring and an upper focus ring. The lower focus ring is arranged around the chuck. The lower focus ring includes a groove on an upper surface of the lower focus ring. A part of an upper surface of the lower focus ring located on an inner side of the groove is a support area. The support area is flush with an upper surface of the chuck and configured to support the wafer with the chuck. The upper focus ring is ascendingly and descendingly arranged in the groove. In response to the upper focus ring being in the groove, an upper surface of the upper focus ring is higher than the support area. A first position-limiting member is arranged on a lower surface of the upper focus ring and corresponds to the groove. The plurality of focus ring thimbles are distributed along a circumference of the upper focus ring at intervals. Each focus ring thimble of the plurality of focus ring thimbles is ascendingly and descendingly arranged in the carrier device and penetrating a part of the lower focus ring located at a bottom of the groove to lift the upper focus ring when ascending. A second position-limiting member is arranged at an upper end of the focus ring thimble and cooperates with the first position-limiting member when the focus ring thimble lifts the upper focus ring to limit a horizontal position of the upper focus ring on the focus ring thimble.

Embodiments of the present disclosure provide a semiconductor reaction chamber including a carrier device. The carrier device is configured to carry a wafer in a semiconductor reaction chamber. The carrier device includes a chuck, a focus ring, and a plurality of focus ring thimbles. The chuck is arranged in the semiconductor reaction chamber to support the wafer. The focus ring assembly includes a lower focus ring and an upper focus ring. The lower focus ring is arranged around the chuck. The lower focus ring includes a groove on an upper surface of the lower focus ring. A part of an upper surface of the lower focus ring located on an inner side of the groove is a support area. The support area is flush with an upper surface of the chuck and configured to support the wafer with the chuck. The upper focus ring is ascendingly and descendingly arranged in the groove. In response to the upper focus ring being in the groove, an upper surface of the upper focus ring is higher than the support area. A first position-limiting member is arranged on a lower surface of the upper focus ring and corresponds to the groove. The plurality of focus ring thimbles are distributed along a circumference of the upper focus ring at intervals. Each focus ring thimble of the plurality of focus ring thimbles is ascendingly and descendingly arranged in the carrier device and penetrating a part of the lower focus ring located at a bottom of the groove to lift the upper focus ring when ascending. A second position-limiting member is arranged at an upper end of the focus ring thimble and cooperates with the first position-limiting member when the focus ring thimble lifts the upper focus ring to limit a horizontal position of the upper focus ring on the focus ring thimble.

The present disclosure has the following beneficial effects.

In the carrier device of the present disclosure, a split focus ring assembly can be included. That is, the focus ring assembly can include an upper focus ring and a lower focus ring. An upper surface of the lower focus ring can include a groove, and an area of the upper surface of the lower focus ring located on the inner side of the groove can be a support area. The support area can be flush with the upper surface of the chuck and can be configured to support the wafer with the chuck together. The upper focus ring can be ascendingly and descendingly arranged in the groove. Thus, the height can be increased by ascending the upper focus ring to compensate for the part of the upper focus ring that is etched to ensure etching uniformity. Meanwhile, since the wafer is supported by the lower focus ring, and the lower focus ring does not ascend with the upper focus ring, the wafer lifting by the upper focus ring can be avoided, which does not affect the absorption and position precision of the wafer. In addition, by arranging the first position-limiting member on the lower surface of the upper focus ring and the second position-limiting member on the upper end of the focus ring thimbles, each focus ring thimble can be ascendingly and descendingly arranged in the carrier device and pass through the part of the lower focus ring located at the bottom of the groove to lift the upper focus ring when ascending. Meanwhile, the second position-limiting member can cooperate with the first position-limiting member when the focus ring thimbles lift the upper focus ring to limit the horizontal position of the upper focus ring on the focus ring thimbles. Thus, the focus ring can be prevented from being displaced and tilted. Therefore, the upper focus ring may not be easy to fall off from the focus ring thimbles to improve the safety of the semiconductor reaction chamber.

In the semiconductor reaction chamber of the present disclosure, the carrier device of the present disclosure can be used. Thus, the impact on the absorption and position precision of the wafer can be avoided, and the upper focus ring may not be easy to fall off from the focus ring thimbles, which improves the safety of the semiconductor reaction chamber.

### BRIEF DESCRIPTION OF THE DRAWINGS

FIG. 1 is a schematic structural diagram of a semiconductor reaction chamber according to some embodiments of the present disclosure.

FIG. 2 is a schematic structural diagram of a carrier device according to some embodiments of the present disclosure.

FIG. 3 is a schematic locally enlarged diagram of FIG. 2.

FIG. 4 is a schematic partial cross-section diagram showing an upper focus ring in a carrier device according to some embodiments of the present disclosure.

FIG. 5 is a schematic partial cross-section diagram showing a bottom focus ring in a carrier device according to some embodiments of the present disclosure.

FIG. 6 is a schematic locally enlarged diagram of a focus ring thimble of a carrier device according to some embodiments of the present disclosure.

FIG. 7 to FIG. 13 are schematic structural diagrams of a driving device of a carrier device according to some embodiments of the present disclosure.

Reference numerals:

| | | |
|---|---|---|
| 100 - Semiconductor reaction | | |
| chamber; | | |
| 200 - Carrier device | 210 - Chuck | 220 - Focus ring assembly |
| 221 - Upper focus ring | 2211 - Position-limiting groove | 222 - Bottom focus ring |
| 2221 - Inner focus ring | 2222 - Outer focus ring | 2222a - Through-hole |
| 223 - Groove | 2231 - First opening groove | |
| 2232 - Second opening groove | 2233 - First mating surface | |
| 2234 - Second mating surface | 2235 - Third mating surface | 230 - Base ring |
| 300 - Focus ring thimble | 301 - Outer surface of second | |
| | position-limiting member | |
| 400 - Driving device | 410 - First driving source | 420 - First fixed bracket |
| 430 - First adapter | 441 - First sliding rail assembly | |
| 442 - Second sliding rail assembly | 450 - Second driving source | |
| 460 - Second fixed bracket | 470 - Second adapter | |
| 480 - Third sliding rail assembly | 491 - First sensor | 492 - Second sensor |
| 500 - Housing | | |
| 600 - Wafer | | |
| 700 - Transfer manipulator | | |
| 800 - Wafer thimble | | |

### DETAILED DESCRIPTION OF THE EMBODIMENTS

To make the objectives, technical solutions, and advantages of the present disclosure clearer, the technical solutions of the present disclosure are described in detail below in connection with embodiments of the present disclosure and the accompanying drawings. Obviously, the described embodiments are only some, but not all, embodiments of the present disclosure. Based on embodiments of the present disclosure, all other embodiments obtained by those of ordinary skill in the art without creative efforts shall be within the scope of the present disclosure.

The technical solutions of embodiments of the present disclosure are described in detail below in connection with the accompanying drawings.

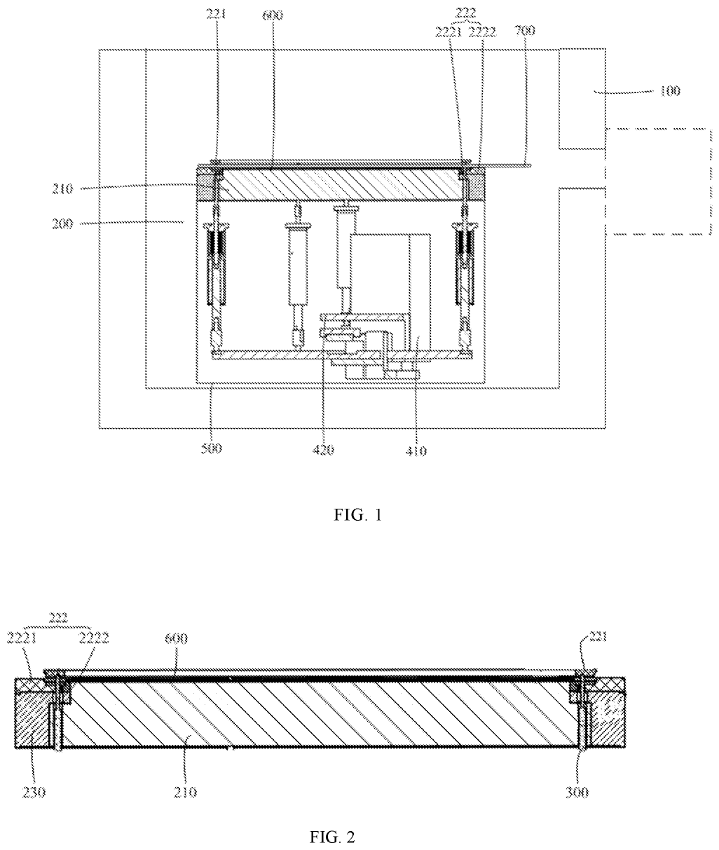

As shown in FIG. 1 and FIG. 2, embodiments of the present disclosure provide a carrier device 200. The carrier device 200 can be configured to carry a wafer 600 in a semiconductor reaction chamber 100. The carrier device 200 includes a chuck 210, a focus ring assembly 220, and a plurality of focus ring thimbles 300.

The chuck 210 is arranged in the semiconductor reaction chamber 100 and configured to carry the wafer 600. The chuck 210 can be, for example, an electrostatic chuck, which is configured to fix the wafer 600 by electrostatic adsorption to prevent the wafer 600 from being displaced during processing.

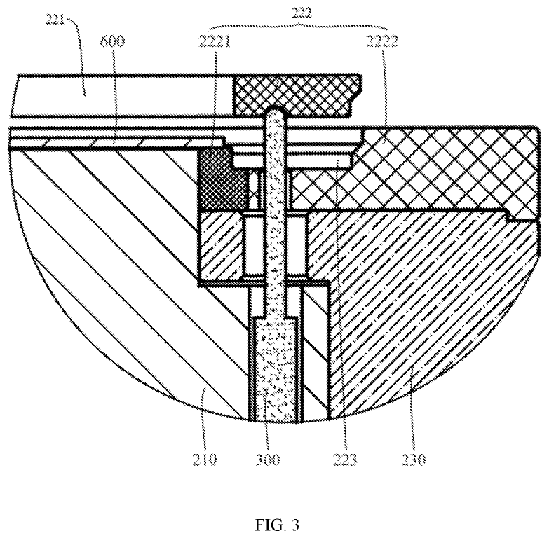

The focus ring assembly 220 includes an upper focus ring 221 and a lower focus ring 222. The lower focus ring 222 is arranged around the chuck 210. As shown in FIG. 3, a groove 223 is provided on an upper surface of the lower focus ring 222, and the upper focus ring 221 is ascendingly and descendingly arranged in the groove 223. That is, at least a part of the upper focus ring 221 can descend into the groove 223 or ascend outside the groove 223. An area on the upper surface of the lower focus ring 222 and an inner side of the groove 223 can be a support area. The support area can be flush with the upper surface of the chuck 210 and configured to support the wafer 600 together. This focus ring assembly 220 can have a split structure, that is, include the upper focus ring 221 and the lower focus ring 222. The lower focus ring 222 and the chuck 210 are configured to jointly support the wafer 600. Meanwhile, the upper focus ring 221 can be ascendingly and descendingly arranged in the groove 223 to increase a height of the upper focus ring 221 by ascending the upper focus ring 221 to compensate for the part of the upper focus ring 221 that is etched. Thus, the etching uniformity can be ensured. Meanwhile, since the wafer 600 is supported by the lower focus ring 222, and the lower focus ring 222 does not ascend with the upper focus ring, the wafer being lifted by the upper focus ring can be avoided. Thus, the absorption and position precision of the wafer 600 may not be affected to affect the etching process.

Moreover, when the upper focus ring 221 is arranged in the above groove 223, the upper surface of the upper focus ring 221 is higher than the above support area. The part of the upper focus ring 221 that is higher than the support area can shield the plasma to reduce the edge etching rate of the wafer to improve the etching uniformity.

In some embodiments, a diameter of an inner annular surface of the upper focus ring 221 can be larger than a diameter of the wafer 600. Thus, an annular gap can be formed between the upper focus ring 221 and the wafer 600. The annular gap can make an edge of the wafer more accessible to the plasma, which is beneficial to increase the edge etching rate of the wafer. Since the part of the upper focus ring 221 that is higher than the support area can shield the plasma and reduce the edge etching rate of the wafer, a height difference between the upper surface of the upper focus ring 221 and an upper surface of the wafer 600 can cause the edge of the wafer 600 less accessible to the plasma to reduce the edge etching rate of the wafer 600, which is opposite to the annular gap. Thus, the upper focus ring 221 with the corresponding height difference and the annular gap may need to be selected according to processing requirements. In some embodiments, the height difference can be greater than or equal to 2 mm and smaller than or equal to 4 mm. A radial width of the annular gap can be greater than or equal to 1 mm and smaller than or equal to 3 mm.

In addition, the lower surface of the upper focus ring 221 can be provided with a first position-limiting member. The first position-limiting member can be arranged corresponding to the groove 223. That is, when the upper focus ring 221 is arranged in the groove 223, a position-limiting groove 2211 can be also arranged within groove 223. The plurality of focus ring thimbles 300 can be distributed along a circumference of the upper focus ring 221 at intervals. Thus, the upper focus ring 221 can be stressed uniformly to prevent the upper focus ring 221 from being tilted. In some embodiments, a number of the focus ring thimbles 300 can be four. In some other embodiments, the number of the focus ring thimbles 300 can be two, three, or more than five.

In some embodiments, the carrier device can further include a driving device 400 configured to drive the plurality of focus ring thimbles 300 to ascend and descend synchronously. In some embodiments, the driving device 400 can be a power structure such as a servo motor, an air cylinder, etc. The driving device 400 can be other power structures, which are not limited here.

Each focus ring thimble 300 can be ascendingly and descendingly arranged in the above carrier device 200 and penetrate a part of the lower focus ring 222 located at the bottom of the above groove 223. Thus, the focus ring thimble 300 can lift the upper focus ring 221 when ascending. A second position-limiting member can be arranged at the upper end of the focus ring thimble 300. The second position-limiting member can cooperate with the first position-limiting member when the focus ring thimble 300 lifts the upper focus ring 221 to limit a horizontal position of the upper focus ring 221 on the focus ring thimble 300. By using the first position-limiting member and the second position-limiting member to limit the horizontal position of the upper focus ring 221 on the focus ring thimble 300, the position of the upper focus ring 221 on the focus ring thimble can be prevented from being displaced and tilted. Thus, the upper focus ring 221 is not easy to fall off from the focus ring thimble 300, and the safety of the semiconductor reaction chamber can be further improved.

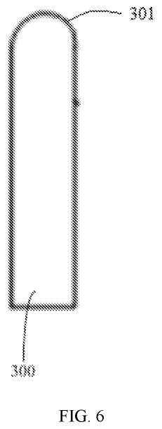

In some embodiments, as shown in FIG. 5, the first position-limiting member is the position-limiting groove 2211 formed on the lower surface of the upper focus ring 221. As shown in FIG. 6, an outer surface 301 of the second position-limiting member cooperates with an inner surface of the position-limiting groove 2211. For a specific cooperation manner, reference can be made to FIG. 3. By causing the position-limiting groove 2211 to cooperate with the second position-limiting member, the position of the upper focus ring 221 in a horizontal direction can be limited. In some embodiments, a moving direction of the focus ring thimble 300 can be a vertical direction. The focus ring thimble 300 can cooperate and be position-limited in the horizontal direction with the position-limiting groove 2211 through the above second position-limiting member.

In some embodiments, the outer surface 301 of the second position-limiting member and the inner surface of the position-limiting groove 2211 can be flat surfaces. That is, an end surface facing upward of the outer surface 301 of the second position-limiting member can be a flat surface. A surface facing downward of the inner surface of the position-limiting groove 2211 can be a flat surface. Thus, when the focus ring thimble 300 extends into the position-limiting groove 2211, the end surface of the second position-limiting member can easily interfere with the edge of the position-limiting groove 2211. Moreover, the upper focus ring 221 can easily become tilted and fall off from the upper focus ring thimble 221.

Based on this, in some other embodiments, as shown in FIG. 5 and FIG. 6, a shape of an orthographic projection of the outer surface 301 of the second position-limiting member and the inner surface of the position-limiting groove 2211 on the vertical plane can be arc-shaped. That is, the outer surface 301 of the second position-limiting member can be an arc-shaped convex surface, and the inner surface of the position-limiting groove 2211 can be an arc-shaped concave surface. Thus, the outer surface 301 of the second position-limiting member can be relatively smooth, and the outer surface 301 of the second position-limiting member is not easy to interfere with the edge of the position-limiting groove 2211. Thus, it is not easy to cause the upper focus ring 221 to be tilted, which further improves the safety and reliability of the carrier device 200. In addition, by causing the shapes of the orthogonal projections of the outer surface 301 of the second position-limiting member and the inner surface of the position-limiting groove 221 on the vertical plane can be arc-shaped, the positioning precision of the second position-limiting member and the position-limiting groove 2211 can be improved to cause the upper focus ring 221 to have a relatively high coaxial degree.

In some embodiments, the position-limiting groove 2211 can be an annular groove, and the annular groove and the upper focus ring 221 can be arranged concentrically. In this solution, the position of the upper focus ring 221 can be limited in the horizontal direction, and the upper focus ring 221 can rotate around a center of the annular groove. Thus, the position of the upper focus ring 221 can be self-adjusted through the rotation to further improve the stability of the ascending and descending of the focus ring 221.

In some embodiments, the lower focus ring 222 can be an integrated structure. However, a side of the lower focus ring 222 close to the wafer 600 can be easily etched. That is, the position where the support area is located can be easily etched. When the support area is etched, the entire lower focus ring 222 may need to be replaced. Thus, the service life of the lower focus ring 222 can be short, and the carrier device 200 may have poor economic performance.

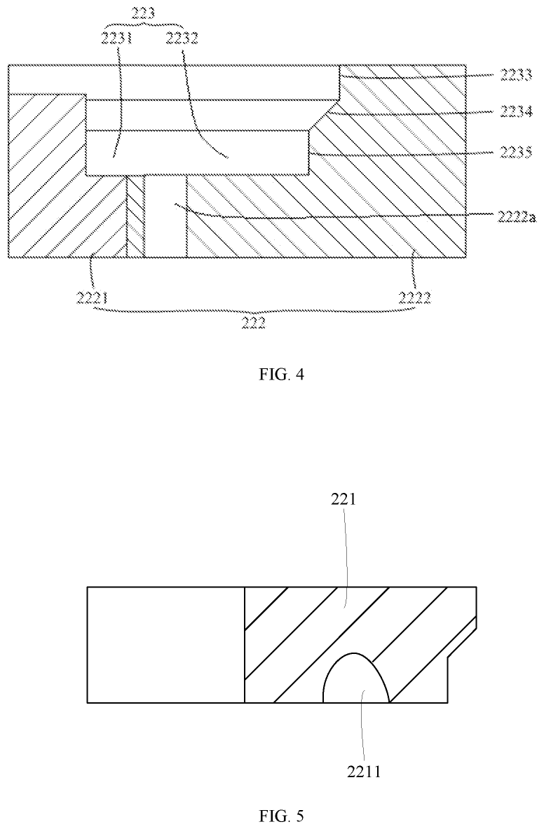

Based on this, in some other embodiments, the lower focus ring 222 can include an inner focus ring 2221 and an outer focus ring 2222. The outer focus ring 2222 can be arranged around the inner focus ring 2221. A groove 223 can be formed on at least one of the upper surface of the inner focus ring 2221 and the upper surface of the outer focus ring 2222, and the support area can be formed on the upper surface of the inner focus ring 2221. For example, as shown in FIG. 4, the groove 223 is divided into two members (e.g., the first opening groove 2231 and the second opening groove 2232 in FIG. 4) formed on the upper surface of the inner focus ring 2221 and the upper surface of the outer focus ring 2222, respectively. Thus, the space occupied by the groove 223 on the inner focus ring 2221 and the outer focus ring 2222 can be reduced to further improve the strength of the inner focus ring 2221 and the outer focus ring 2222. Of course, in practical applications, the groove 223 may also be formed only on the upper surface of the inner focus ring 2221 or the upper surface of the outer focus ring 2222. In some embodiments, the inner focus ring 2221 can be arranged close to the wafer 600. Thus, the inner focus ring 2221 can be easily etched. The outer focus ring 2222 can be far away from the wafer 600. Thus, the outer focus ring 2222 cannot be easily etched. Thus, when the outer focus ring 2222 is not etched, only the inner focus ring 2221 may need to be replaced. Therefore, the service life of the lower focus ring 222 can be improved, and the carrier device 200 can have relatively good economic performance.

In some embodiments, as shown in FIG. 4, the diameter of the outer annular surface of the inner focus ring 2221 is equal to the diameter of the inner annular surface of the outer focus ring 2222 to ensure that no gap exists between the inner focus ring 2221 and the outer focus ring 2222. Moreover, the outer annular surface of the inner focus ring 2221 is located on an inner side of the circumference where the plurality of focus ring thimbles 300 are located. In addition, a plurality of through-holes 2222a are arranged at the part of the outer focus ring 2222 that is located at the bottom of the groove 223. A number of the through-holes 2222a can be equal to a number of the focus ring thimbles 300. The focus ring thimbles 300 can pass through the through-holes 2222a in a one-to-one correspondence to extend into the groove 223. By arranging the through-hole 2222a on the outer focus ring 2222, a distance between the focus ring thimble 300 and the wafer 600 can be increased, and the impact of the movement of the focus ring thimble 300 on the wafer 600 can be avoided.

Since the inner focus ring 2221 is easy to be etched, in some other embodiments, the inner focus ring 2221 can be made of an etch-resistant material, which can improve the service life of the inner focus ring 2221. In some embodiments, the inner focus ring 2221 can be made of materials such as quartz or silicon carbide. Quartz and silicon carbide can have advantages of a small thermal expansion coefficient, not easy to generate polluting particles, and high processing performance and chemical stability. In some other embodiments, the inner focus ring 2221 can also be made of another corrosion-resistant material, which is not limited here.

In some other embodiments, the upper focus ring 221 can be made of an etching-resistant material, which can improve the service life of the upper focus ring 221. Thus, the economic performance of the carrier device 200 can be improved, and the continuity of the etching process can be ensured. In some embodiments, since the upper focus ring 221 is easily etched, the upper focus ring 221 can be made of a silicon carbide material. In some other embodiments, the upper focus ring 221 can also be made of another material, which is not limited here.

In some embodiments, to improve the assembly accuracy of the upper focus ring 221 and the lower focus ring 222, as shown in FIG. 4, an outer annular side surface of the groove 223 is a first stepped surface. As shown in FIG. 3, the outer annular surface of the upper focus ring 221 is a second stepped surface. The second stepped surface can cooperate with the first stepped surface to define the position of the upper focus ring 221 in the groove 223. Thus, with the cooperation of the second stepped surface and the first stepped surface, the installation position of the upper focus ring 221 and the lower focus ring 222 can be limited. Therefore, the assembly accuracy of the upper focus ring 221 and the lower focus ring 222 can be improved to cause the upper focus ring 221 and the lower focus ring 222 to have a good coaxial degree.

Further, as shown in FIG. 4, the above first stepped surface includes, for example, a first mating surface 2233, a second mating surface 2234, and a third mating surface 2235 connected in sequence from top to bottom. The first mating surface 2233 and the third mating surface 2235 can be perpendicular to the upper surface of the lower focus ring 222. A diameter of the third mating surface 2235 is smaller than a diameter of the first mating surface 2233. A diameter of the second mating surface 2234 can decrease from top to bottom. Correspondingly, the above second stepped surface can include a fourth mating surface, a fifth mating surface, and a sixth mating surface that are connected from top to bottom in sequence. The fourth mating surface, the fifth mating surface, and the sixth mating surface can cooperate with the first mating surface 2233, the second mating surface 2234, and the third mating surface 2235. Thus, The upper focus ring 221 can be assembled with the lower focus ring 222. Since the diameter of the second mating surface 2234 decreases from top to bottom, a sloped annular surface can be formed. The upper focus ring 221 can slide relatively on the second mating surface 2234 under the gravity of the upper focus ring 221 to automatically calibrate the position of the upper focus ring 221. Thus, when the upper focus ring 221 descends into the groove 223, the upper focus ring 221 can automatically reach the position that is coaxial with the upper focus ring 221. Thus, the coaxial degree of the upper focus ring 221 and the lower focus ring 222 can be further improved. In addition, by causing the diameter of the third mating surface 2235 to be smaller than the diameter of the first mating surface 2233, the opening size of the groove 223 can be increased. Moreover, by using the slope surface formed by the second mating surface 2234, the upper focus ring 221 may not be easy to interfere with the lower focus ring when the upper focus ring 221 descends. Thus, the safety of the carrier device 200 can be further improved.

In some embodiments, as shown in FIG. 1, the carrier device 200 of embodiments of the present disclosure further includes a housing 500. The housing 500 can form a closed space with a lower surface of the chuck 210. The driving device 400 is arranged in the enclosed space. Then, the housing 500 can be configured to cover the driving device 400 inside to prevent the driving device 400 from being directly exposed to the plasma environment. Further, the sidewall of the housing 500 and the inner wall of the reaction chamber 100 can be sealed and connected through an aluminum base. The aluminum base can be in the atmospheric state to facilitate the connection of the aluminum base to required cables, pipelines, etc.

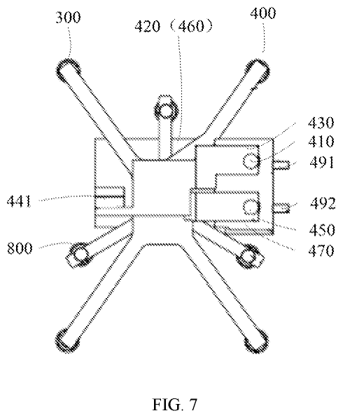

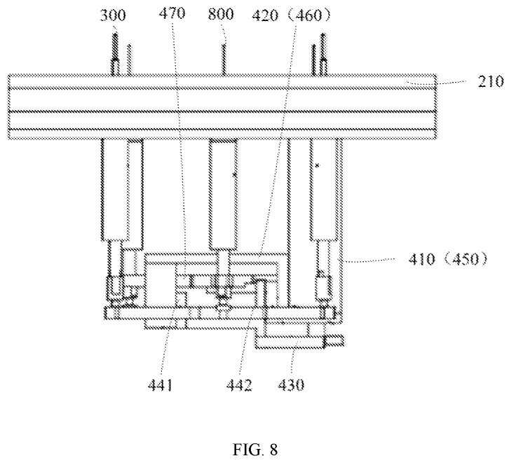

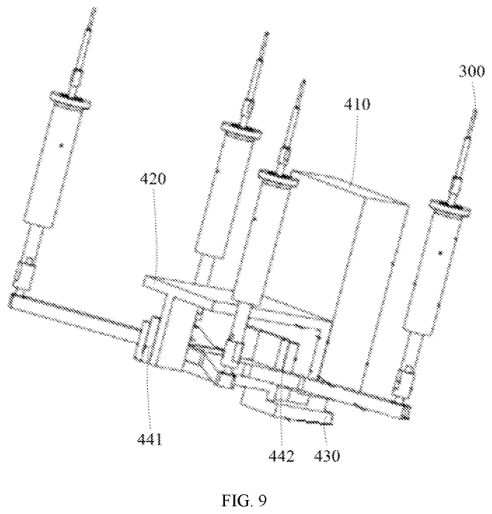

The present disclosure provides a specific structure of the driving device 400. In some other embodiments, the driving device 400 can have another structure, which is not limited here. In some embodiments, as shown in FIG. 7, FIG. 8, and FIG. 9, the driving device 400 includes a first driving source 410, a first fixing bracket 420, a first adapter 430, a first sliding rail assembly 441, and a second sliding rail assembly 442. A fixed end of the first driving source 410 can be fixedly connected to the housing 500. In some other embodiments, the fixed end of the first driving source 410 can also be fixedly connected to another member such as the first fixing bracket 420, as long as the first driving source 410 can be fixed under the chuck 210. A driving end of the first driving source 410 can be connected to the focus ring thimble 300 through the first adapter 430.

In some embodiments, the first drive source 410 can drive the first adapter 430 to move. The first adapter 430 can drive the focus ring thimble 300 to move.

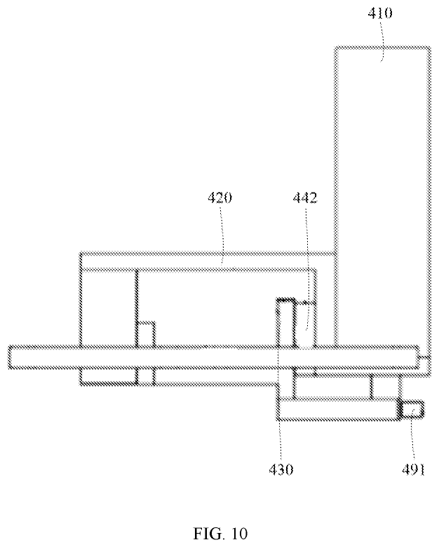

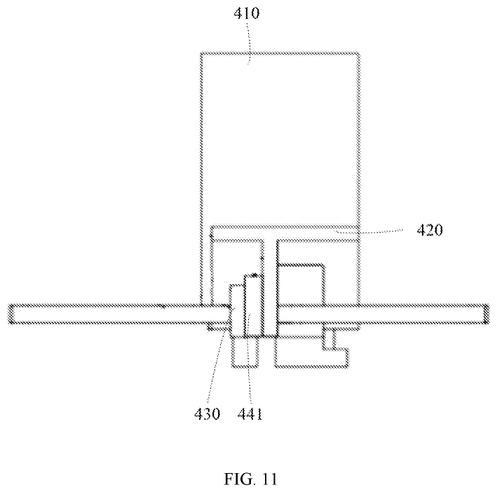

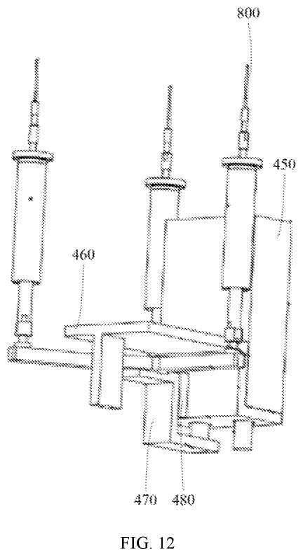

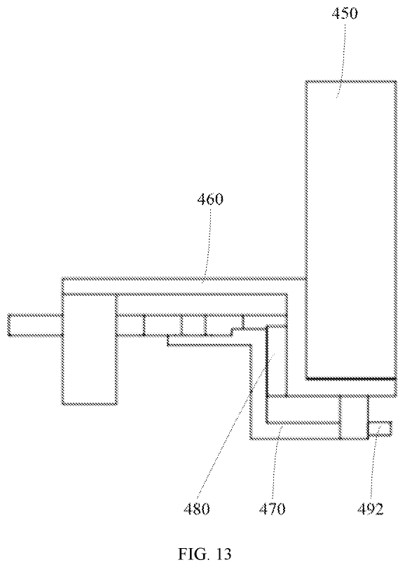

As shown in FIG. 10 to FIG. 13, the first fixing bracket 420 is fixedly connected to the housing 500. In some other embodiments, the first fixing bracket 420 can be fixedly connected to another member such as the fixing end of the first driving source 410, as long as the first driving source 410 can be fixed under the chuck 210. The first fixing bracket 420 can include a first mounting surface and a second mounting surface. The first mounting surface and the second mounting surface can be parallel to the movement direction of the focus ring thimble 300. The first mounting surface can be perpendicular to the second mounting surface. The first sliding rail assembly 441 and the second sliding rail assembly 442 can be arranged on the first mounting surface and the second mounting surface and slidingly connected to the first adapter 430 to limit the movement direction of the focus ring thimble 300.

Thus, since the first mounting surface and the second mounting surface can be perpendicular to each other, a plane where a rail opening of the first sliding rail assembly 441 is located can be perpendicular to a plane where a rail opening of the second sliding rail assembly 442 is located. Thus, rail directions of the sliding rail assembly can be in two directions perpendicular to each other. Therefore, rail tolerances can be prevented from accumulating in a same direction to improve the movement accuracy of the focus ring thimble 300. In addition, the structure of the double sliding rail assemblies can increase the rigidity of the focus ring thimble 300 in the movement direction of the focus ring thimble 300. Thus, the movement of the upper focus ring 221 can be more stable.

In some embodiments, the first sliding rail assembly 441 can include a guide rail and a slider. The guide rail and the slider can slidably cooperate with each other. The guide rail can be arranged at the first fixing bracket 420. The slider can be connected to the first adapter 430. The second sliding rail assembly 442 can have the same structure as the first sliding rail assembly 441, which is not repeated here.

In some other embodiments, the driving device 400 can further include a first sensor 491 and a first control unit. The first sensor 491 can be configured to detect position information of the focus ring thimble 300 and feedback the position information to the first control unit. The first control unit can be configured to control the operation of the first driving source 410 according to the position information. Thus, with the first sensor 491 and the first control unit, the movement of the focus ring thimble 300 can be precisely controlled. Therefore, the movement precision of the upper focus ring 221 can be high. For example, the first driving source 410 can be an electric cylinder. The above first control unit can be a controller integrated in the electric cylinder. In addition, since the electric cylinder is not easy to have a backlash phenomenon due to the combination of the connection members, the electric cylinder can have better positioning accuracy. Thus, the movement accuracy of the upper focus ring 221 can be further improved.

To improve the compensation accuracy of the upper focus ring 221, in some other embodiments, after the upper focus ring 221 is etched for the first time, the driving device 400 can drive the upper focus ring 221 to ascend to a preset height. The preset height can be equal to an etched amount of the upper focus ring 221. The preset height can be between 0 and 2 mm. The driving device 400 can drive the upper focus ring 221 to descend until the focus ring thimble 300 moves to a lowest position. Then, the driving device 400 can drive the focus ring thimble 300 to ascend again until the upper focus ring 221 ascends to the preset height. Thus, by lifting the upper focus ring 221 two times, a movement gap of the focus ring thimble 300 can be eliminated to improve the movement accuracy of the upper focus ring 221.

To facilitate the replacement of the upper focus ring 221, in some other embodiments, the semiconductor reaction chamber 100 can further include a transfer manipulator 700. The transfer manipulator 700 can be configured to transfer the upper focus ring 221 and the wafer 600. Thus, the upper focus ring 221 can be replaced without opening the semiconductor reaction chamber 100 to improve the replacement efficiency of the upper focus ring 221 and further improve the process efficiency of the semiconductor reaction chamber 100. In addition, the upper focus ring 221 can be replaced by the transfer manipulator 700, which also reduces the labor intensity of the operator.

In some embodiments, when the upper focus ring 221 needs to be moved out of the semiconductor reaction chamber 100, the driving device 400 can be firstly controlled to drive the upper focus ring 221 to ascend to a certain height. Then, the transfer manipulator 700 can be controlled to pass through the opening at the sidewall of the semiconductor reaction chamber 100 to extend into the semiconductor reaction chamber 100. Meanwhile, the transfer manipulator 700 can be controlled to move to a lower side of the upper focus ring 221. Then, the driving device 400 can be controlled to drive the upper focus ring 221 to descend. Thus, the upper focus ring 221 can be transferred to the transfer manipulator 700. Then, the transfer manipulator 700 can be controlled to transfer the upper focus ring 221 out of the semiconductor reaction chamber 100 through the opening on the sidewall of the semiconductor reaction chamber 100.

When the upper focus ring 221 needs to be moved into the semiconductor reaction chamber 100, the upper focus ring 221 can be placed on the transfer manipulator 700. The transfer manipulator 700 can be controlled to pass through the opening on the sidewall of the semiconductor reaction chamber to extend into the semiconductor reaction chamber 100. Then, the driving device 400 can be controlled to drive the focus ring thimble 300 to ascend to lift the upper focus ring 221. Thus, the upper focus ring 221 can be transferred to the focus ring thimble 300. Then, the transfer manipulator 700 can be removed. Then, the driving device 400 can be controlled to drive the focus ring thimble 300 to descend to lower the focus ring to a preset position to complete the replacement operation of the upper focus ring 221.

The carrier device 200 of the present disclosure further can include a plurality of wafer thimbles 800. The plurality of wafer thimbles 800 can be distributed along the circumferential direction of the chuck 210 at intervals. The wafer thimbles 800 can be configured to drive the wafer 600 to ascend and descend. The ascending and descending operation of the wafer thimbles 800 can be realized by the driving device 400. In some embodiments, the driving device 400 can further include a second driving source 450, a second fixing bracket 460, a second adapter 470, and a third sliding rail assembly 480. A fixed end of the second driving source 450 can be fixedly connected to the housing 500 or another member, as long as the second driving source 450 can be fixed under the chuck 210. A driving end of the second driving source 450 can be connected to the wafer thimble 800 through the second adaptor 470.

In some embodiments, the second driving source 450 can drive the second adapter 470 to move, and the second adapter 470 can drive the wafer thimbles 800 to move.

The second fixing bracket 460 can be fixedly connected to the fixed end of the second driving source 450 or another member, as long as the second fixing bracket can be fixed under the chuck 210. The second fixing bracket 460 can include a third mounting surface. The third mounting surface can be parallel to a moving direction of the wafer thimbles 800. The third sliding rail assembly 480 can be arranged on the third mounting surface and can be slidably connected to the second adapter 470 to limit the moving direction of the wafer thimbles 800.

Thus, the mating precision of the sliding rail assembly can be high, and the rigidity and stability of the ascending and descending of the wafer thimbles 800 can be further improved. Therefore, the wafer 600 may not be easy to slide when being lifted, and the wafer 600 may not be easy to fall off, which further improves the reliability of the semiconductor reaction chamber 100.

In some embodiments, a number of the wafer thimbles 800 can be three, and the three wafer thimbles 800 can be evenly distributed along the circumferential direction of the chuck 210. Thus, the wafer 600 can be evenly supported, and the wafer 600 can be more stably supported. In some other embodiments, the number of the wafer thimbles 800 may have another number, which is not limited here.

In some embodiments, the structure of the third sliding rail assembly 480 can be the same as the structure of the first sliding rail assembly 441. A guide rail of the third sliding rail assembly 480 can be connected to the second fixing bracket 460. A slider of the third sliding rail assembly 480 can be connected to the second adapter 470.

In embodiments of the present disclosure, the driving device 400 can further include a second sensor 492 and a second control unit. The second sensor 492 can be configured to detect the position information of the wafer thimbles 800 and feedback on the position information to the second control unit. The second control unit can be configured to control the operation of the second driving source 450 according to the position information. Thus, with the second sensor 492 and the second control unit, the movement of the wafer thimbles 800 can be precisely controlled. Therefore, the movement precision of the wafer 600 can be high. For example, the second driving source 450 can be an electric cylinder. The above second control unit can be a controller integrated into the electric cylinder.

In some embodiments, the driving device 400 can include a dual-shaft driving source. The first driving source 410 and the second driving source 450 can be two different driving shafts of the dual-shaft driving source. That is, the drive device 400 can include one driving source. The first adapter 430 and the second adapter 470 can be connected to different driving shafts on the driving source. The driving shaft connected to the first adapter 430 can be configured to drive the focus ring thimbles 300. The driving shaft connected to the second adapter 470 can be configured to drive the wafer thimbles 800.

In embodiments of the present disclosure, since the first fixing bracket 420 and the second fixing bracket 460 are non-moving parts, the first fixing bracket 420 and the second fixing bracket 460 can have an integrated structure. Thus, the first sliding rail assembly 441, the second sliding rail assembly 442, and the third sliding rail assembly 480 can be mounted on a same fixed bracket. Therefore, a number of members of the carrier device 200 can be less to further simplify the composition structure of the carrier device 200.

The carrier device 200 of embodiments of the present disclosure can further include a base ring 230. The base ring 230 can be arranged around the chuck 210. The base ring 230 can be configured to support the lower focus ring 222. An interface disk can be arranged at the bottom of the base ring 230. The focus ring thimbles 300 can be inserted from one side of the interface disk. Bellows can be sleeved at the focus ring thimbles 300. One end of the bellows can be connected to the focus ring thimbles 300, and the other end of the bellows can be connected to the interface disk, which can maintain a sealed effect for the focus ring thimbles 300 during the movement process.

Based on the carrier device of embodiments of the present disclosure, embodiments of the present disclosure further provide the semiconductor reaction chamber. The semiconductor reaction chamber can include the carrier device of embodiments of the present disclosure.

In the semiconductor reaction chamber of the present disclosure, by using the above carrier device of the present disclosure, the impact on the absorption and position precision of the wafer due to the ascending of the upper focus ring can be avoided, and the upper focus ring may not be easy to fall off to further improve the safety of the semiconductor reaction chamber.

In embodiments of the present disclosure, the differences between the various embodiments are mainly described. As long as different optimization features of the various embodiments are not contradictory, the optimization features can be combined to form better embodiments, which are not repeated here.

The above description is merely embodiments of the present disclosure and is not intended to limit the present disclosure. Various modifications and variations of the present disclosure are possible for those skilled in the art. Any modification, equivalent replacement, and improvement made within the spirit and principle of the present disclosure shall be within the scope of the claims of the invention.

What is claimed is:

1. A carrier device configured to carry a wafer in a semiconductor reaction chamber comprising:
a chuck arranged in the semiconductor reaction chamber to support the wafer;
a focus ring assembly including:
a lower focus ring arranged around the chuck and including a groove on an upper surface of the lower focus ring, a part of an upper surface of the lower focus ring located on an inner side of the groove being a support area, the support area being flush with an upper surface of the chuck and configured to support the wafer with the chuck;
an upper focus ring ascendingly and descendingly arranged in the groove, in response to the upper focus ring being in the groove, an upper surface of the upper focus ring being higher than the support area, a first position-limiting member being arranged on a lower surface of the upper focus ring and corresponding to the groove;
a plurality of focus ring thimbles distributed along a circumference of the upper focus ring at intervals, each focus ring thimble of the plurality of focus ring thimbles being ascendingly and descendingly arranged in the carrier device and penetrating a part of the lower focus ring located at a bottom of the groove to lift the upper focus ring when ascending, a second position-limiting member being arranged at an upper end of the focus ring thimble and cooperating with the first position-limiting member when the focus ring thimble lifts the upper focus ring to limit a horizontal position of the upper focus ring on the focus ring thimble.

2. The carrier device according to claim 1, wherein:
the lower focus ring includes an inner focus ring and an outer focus ring, the outer focus ring being arranged around the inner focus ring; and
the groove is formed on at least one of an upper surface of the inner focus ring or an upper surface of the outer focus ring, and the support area is formed on the upper surface of the inner focus ring.

3. The carrier device according to claim 2, wherein:
a diameter of an outer annular surface of the inner focus ring is equal to a diameter of an inner annular surface of the outer focus ring;
the outer annular surface of the inner focus ring is located on an inner side of a circumference where the plurality of focus ring thimbles are located;
a plurality of through-holes are arranged at a part of the outer focus ring located at the bottom of the groove;
a number of the through-holes is equal to a number of the plurality of focus ring thimbles; and
the plurality of focus ring thimbles pass through the through-holes in a one-to-one correspondence to extend into the groove.

4. The carrier device according to claim 1, wherein:
an outer annular side surface of the groove includes a first stepped surface;
the outer annular surface of the upper focus ring includes a second stepped surface; and
the second stepped surface cooperates with the first stepped surface to limit a position of the upper focus ring in the groove.

5. The carrier device according to claim 4, wherein:
the first stepped surface includes a first mating surface, a second mating surface, and a third mating surface connected in sequence from top to bottom;
the first mating surface and the third mating surface are perpendicular to the upper surface of the lower focus ring;
a diameter of the third mating surface is smaller than a diameter of the first mating surface; and
a diameter of the second mating surface decreases from top to bottom;
the second stepped surface includes a fourth mating surface, a fifth mating surface, and a sixth mating surface, and the fourth mating surface, the fifth mating surface, and the sixth mating surface cooperate with the first mating surface, the second mating surface, and the third mating surface, respectively.

6. The carrier device according to claim 1, wherein:
the first position-limiting member is a position-limiting groove; and
an outer surface of the second position-limiting member cooperates with an inner surface of the position-limiting groove.

7. The carrier device according to claim 6, wherein orthogonal projections of the outer surface of the second position-limiting member and the inner surface of the position-limiting groove are arc-shaped.

8. The carrier device according to claim 6, wherein the position-limiting groove is an annular groove arranged coaxially with the upper focus ring.

9. The carrier device according to claim 1, wherein a diameter of an inner annular surface of the upper focus ring is greater than a diameter of the wafer.

10. The carrier device according to claim 2, wherein:
the inner focus ring is made of an etch-resistant material; and/or
the upper focus ring is made of an etch-resistant material.

11. The carrier device according to claim 1, further comprising a driving device configured to drive the plurality of focus ring thimbles to ascend and descend synchronously and including:
a first adaptor;
a first driving source, an end of the first driving source being fixed under the chuck, and a driving end of the first driving source being connected to the focus ring thimbles through the first adaptor;
a first fixing bracket fixed under the chuck and including a first mounting surface and a second mounting surface, the first mounting surface and the second mounting surface being parallel to a moving direction of the focus ring thimbles, and the first mounting surface being perpendicular to the second mounting surface;
a first sliding rail assembly; and
a second sliding rail assembly, the first sliding rail assembly and the second sliding rail assembly being arranged on the first mounting surface and the second mounting surface, respectively, and slidably connected to the first adaptor to limit a movement direction of the focus ring thimbles.

12. The carrier device according to claim 11, wherein the driving device further includes:
a first sensor configured to detect position information of the focus ring thimbles and feedback on the position information to a first control unit;
the first control unit configured to control an operation of the first driving source according to the position information.

13. The carrier device according to claim 11, further comprising:
a housing forming a sealed space with a lower surface of the chuck, the driving device being arranged in the sealed space, a fixed end of the first driving source being fixedly connected to the housing or the first fixing bracket, the first fixing bracket being fixedly connected to the housing.

14. A semiconductor reaction chamber comprising a carrier device configured to carry a wafer in a semiconductor reaction chamber and including:
a chuck arranged in the semiconductor reaction chamber to support the wafer;
a focus ring assembly including:
a lower focus ring arranged around the chuck and including a groove on an upper surface of the lower focus ring, a part of an upper surface of the lower focus ring located on an inner side of the groove being a support area, the support area being flush with an upper surface of the chuck and configured to support the wafer with the chuck;
an upper focus ring ascendingly and descendingly arranged in the groove, in response to the upper focus ring being in the groove, an upper surface of the upper focus ring being higher than the support area, a first position-limiting member being arranged on a lower surface of the upper focus ring and corresponding to the groove;
a plurality of focus ring thimbles distributed along a circumference of the upper focus ring at intervals, each focus ring thimble of the plurality of focus ring thimbles being ascendingly and descendingly arranged in the carrier device and penetrating a part of the lower focus ring located at a bottom of the groove to lift the upper focus ring when ascending, a second position-limiting member being arranged at an upper end of the focus ring thimble and cooperating with the first position-limiting member when the focus ring thimble lifts the upper focus ring to limit a horizontal position of the upper focus ring on the focus ring thimble.

15. The semiconductor reaction chamber according to claim 14, wherein:
the lower focus ring includes an inner focus ring and an outer focus ring, the outer focus ring being arranged around the inner focus ring; and
the groove is formed on at least one of an upper surface of the inner focus ring or an upper surface of the outer focus ring, and the support area is formed on the upper surface of the inner focus ring.

16. The semiconductor reaction chamber according to claim 15, wherein:
a diameter of an outer annular surface of the inner focus ring is equal to a diameter of an inner annular surface of the outer focus ring;
the outer annular surface of the inner focus ring is located on an inner side of a circumference where the plurality of focus ring thimbles are located;
a plurality of through-holes are arranged at a part of the outer focus ring located at the bottom of the groove;
a number of the through-holes is equal to a number of the plurality of focus ring thimbles; and
the plurality of focus ring thimbles pass through the through-holes in a one-to-one correspondence to extend into the groove.

17. The semiconductor reaction chamber according to claim 14, wherein:
an outer annular side surface of the groove includes a first stepped surface;
the outer annular surface of the upper focus ring includes a second stepped surface; and
the second stepped surface cooperates with the first stepped surface to limit a position of the upper focus ring in the groove.

18. The semiconductor reaction chamber according to claim 17, wherein:
the first stepped surface includes a first mating surface, a second mating surface, and a third mating surface connected in sequence from top to bottom;
the first mating surface and the third mating surface are perpendicular to the upper surface of the lower focus ring;
a diameter of the third mating surface is smaller than a diameter of the first mating surface; and
a diameter of the second mating surface decreases from top to bottom;
the second stepped surface includes a fourth mating surface, a fifth mating surface, and a sixth mating surface, and the fourth mating surface, the fifth mating surface, and the sixth mating surface cooperate with the first mating surface, the second mating surface, and the third mating surface, respectively.

19. The semiconductor reaction chamber according to claim 14, wherein:
the first position-limiting member is a position-limiting groove; and
an outer surface of the second position-limiting member cooperates with an inner surface of the position-limiting groove.

20. The semiconductor reaction chamber according to claim 17, wherein the carrier device includes a driving device configured to drive the plurality of focus ring thimbles to ascend and descend synchronously and including:
a first adaptor;
a first driving source, an end of the first driving source being fixed under the chuck, and a driving end of the first driving source being connected to the focus ring thimbles through the first adaptor;
a first fixing bracket fixed under the chuck and including a first mounting surface and a second mounting surface, the first mounting surface and the second mounting surface being parallel to a moving direction of the focus ring thimbles, and the first mounting surface being perpendicular to the second mounting surface;
a first sliding rail assembly; and
a second sliding rail assembly, the first sliding rail assembly and the second sliding rail assembly being arranged on the first mounting surface and the second mounting surface, respectively, and slidably connected to the first adaptor to limit a movement direction of the focus ring thimbles.
